(19) United States
(12) Patent Application Publication
(10) Pub. No.: US 2025/0386502 A1
(43) Pub. Date: Dec. 18, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Jehong Oh, Suwon-si (KR); Kyengmun Kang, Suwon-si (KR); Sunggil Kim, Suwon-si (KR); Woosung Lee, Suwon-si (KR); Hanmei Choi, Suwon-si (KR)

(21) Appl. No.: 19/020,597

(22) Filed: Jan. 14, 2025

(30) Foreign Application Priority Data
Jun. 12, 2024 (KR) 10-2024-0076614

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

Provided is a method of manufacturing a semiconductor device, the method including alternately stacking a plurality of insulating films and a plurality of sacrificial insulating films one by one, forming a vertical hole extending in a vertical direction through the plurality of insulating films and the plurality of sacrificial insulating films, forming multiple dielectric films on an inner wall of the vertical hole, forming an amorphous silicon film on the multiple dielectric films, forming an oxide film on the amorphous silicon film, bonding metal atoms on a surface of the oxide film by reacting a metal precursor gas with the surface of the oxide film, forming metal seeds within the amorphous silicon film by diffusing the metal atoms, and forming a channel film including polycrystalline silicon from the amorphous silicon film using the metal seeds.

### CROSS-REFERENCE TO RELATED APPLICATION

This application is based on and claims priority under 35 U.S.C. § 119 to Korean Patent Application No. 10-2024-0076614, filed on Jun. 12, 2024, in the Korean Intellectual Property Office, the disclosure of which is incorporated by reference herein in its entirety.

### BACKGROUND

The inventive concept relates to a semiconductor device and a method of manufacturing the same, and more particularly, to a semiconductor device with a non-volatile vertical memory device and a method of manufacturing the semiconductor device.

With the increase in capacity and high integration of semiconductor devices, vertical memory devices for increasing memory capacity by stacking a plurality of memory cells on a substrate in a vertical direction have been proposed.

As the number of stacks of cells in the vertical direction increases, the electrical properties of the vertical memory devices may deteriorate. Thus, various studies are being conducted on materials used for channels to solve this problem.

### SUMMARY

Aspects of the inventive concept provide a semiconductor device, having memory cells arranged three-dimensionally in a reduced area due to down-scaling, with a structure that can improve electrical characteristics and reliability of the semiconductor device.

Aspects of the inventive concept also provide a method of manufacturing a semiconductor device, having memory cells arranged three-dimensionally in a reduced area due to down-scaling, with a structure that can improve electrical characteristics and reliability of the semiconductor device.

According to an aspect of the inventive concept, there is provided a semiconductor device including a stacked structure in which a plurality of gate lines and a plurality of insulating patterns are alternately stacked in a vertical direction, a channel film extending lengthwise in the vertical direction within a vertical hole passing through the stacked structure in the vertical direction and having a polycrystalline structure, and multiple dielectric films between the plurality of gate lines and the channel film, wherein the number of grains per length of the channel film along a line extending in the vertical direction is 0.07 grain/μm to 2 grains/μm.

According to another aspect of the inventive concept, there is provided a semiconductor device including a peripheral circuit and a memory cell array, wherein the memory cell array includes a stacked structure in which a plurality of gate lines and a plurality of insulating patterns are alternately stacked in a vertical direction, a channel film extending lengthwise in the vertical direction within a vertical hole passing through the stacked structure in the vertical direction, the channel film having a polycrystalline structure, and an oxide film positioned within a columnar space defined by the channel film and extending in the vertical direction in contact with a surface of the channel film, and multiple dielectric films between the plurality of gate lines and the channel film, wherein the channel film includes a plurality of grains, and wherein the number of grains per length of the channel film along a line extending in the vertical direction is 0.07 grain/μm to 2 grains/μm.

According to another aspect of the inventive concept, there is provided a method of manufacturing a semiconductor device, the method including alternately stacking a plurality of insulating films and a plurality of sacrificial insulating films one by one, forming a vertical hole extending in a vertical direction through the plurality of insulating films and the plurality of sacrificial insulating films, forming multiple dielectric films on an inner wall of the vertical hole, forming an amorphous silicon film on the multiple dielectric films, forming an oxide film on the amorphous silicon film, bonding metal atoms on a surface of the oxide film by reacting a metal precursor gas with the surface of the oxide film, forming metal seeds within the amorphous silicon film by diffusing the metal atoms, and forming a channel film including polycrystalline silicon from the amorphous silicon film using the metal seeds.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to some embodiments;

FIG. 2A is a plan layout showing some components of a cell array structure of a semiconductor device according to some embodiments;

FIG. 2B is a cross-sectional view of some regions of a cross-section taken along line X1-X1′ in FIG. 2A;

FIG. 2C is an enlarged cross-sectional view of a region indicated by “EX1” in FIG. 2B;

FIG. 2D is an enlarged cross-sectional view of a region indicated by “EX2” in FIG. 2C;

FIG. 3 is a flowchart of a method of manufacturing a semiconductor device, according to some embodiments; and

FIGS. 4 to 15 are cross-sectional views shown in process order to explain a method of manufacturing a semiconductor device according to some embodiments, wherein FIGS. 4, 5, 6, 7, 8A, 10A, 11, 12, 13, 14, and 15 are enlarged views of a region corresponding to the region indicated by “EX1” in FIG. 2B and FIGS. 8B, 9, and 10B are enlarged views of a region corresponding to the region indicated by “EX2” in FIG. 2C.

### DETAILED DESCRIPTION OF THE EMBODIMENTS

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” “vertical,” “horizontal,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Hereinafter, embodiments are described in detail with reference to the accompanying drawings. The same reference numerals are used for the same components in the drawings, and duplicate descriptions thereof are omitted.

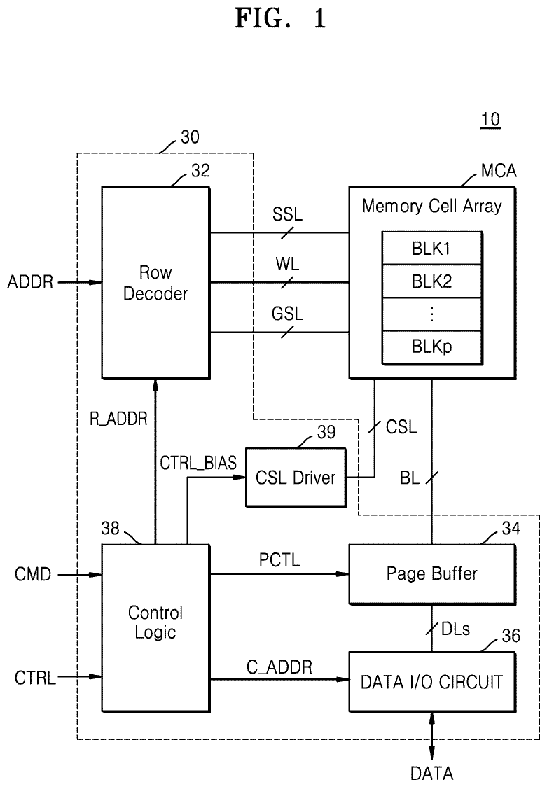

FIG. 1 is a block diagram of a semiconductor device 10 according to some embodiments.

Referring to FIG. 1, a semiconductor device 10 may include a memory cell array MCA and a peripheral circuit 30. The memory cell array MCA includes a plurality of memory cell blocks BLK1 to BLKp. The plurality of memory cell blocks BLK1 to BLKp may each include a plurality of memory cells. The plurality of memory cell blocks BLK1 to BLKp may be electrically connected to the peripheral circuit 30 through bit lines BL, word lines WL, string select lines SSL, and ground select lines GSL.

The peripheral circuit 30 may include a row decoder 32, a page buffer 34, a data input/output (I/O) circuit 36, a control logic 38, and a common source line (CSL) driver 39. The peripheral circuit 30 may further include various circuits, such as a voltage generation circuit for generating various voltages necessary for operations of the semiconductor device 10, an error correction circuit for correcting errors in data read from the memory cell array MCA, an I/O interface, and the like.

The memory cell array MCA may be electrically connected to the row decoder 32 through the word lines WL, the string select lines SSL, and the ground select lines GSL and may be electrically connected to the page buffer 34 through bit lines BL. In the memory cell array MCA, the plurality of memory cells included in the plurality of memory cell blocks BLK1 to BLKp may each include or be a flash memory cell. The memory cell array MCA may include or may be a three-dimensional memory cell array. The three-dimensional memory cell array may include a plurality of NAND strings, wherein each of the plurality of NAND strings may include a plurality of memory cells which are vertically stacked and electrically connected to the plurality of word lines WL.

The peripheral circuit 30 may receive an address ADDR, a command CMD, and a control signal CTRL from the outside of the semiconductor device 10 and may transmit and receive data DATA to and from a device outside the semiconductor device 10.

The row decoder 32 may select at least one of the plurality of memory cell blocks BLK1 to BLKp in response to the address ADDR received from the outside and may select a word line WL, a string select line SSL, and a ground select line GSL of the selected memory cell block. The row decoder 32 may pass a voltage for performing a memory operation to the word line WL of the selected memory cell block.

The page buffer 34 may be electrically connected to the memory cell array MCA through the bit lines BL. The page buffer 34 may operate as a write driver to apply a voltage according to the data DATA to be stored in the memory cell array MCA to the bit lines BL during a program operation and may operate as a sense amplifier to sense the data DATA stored in the memory cell array MCA during a read operation. The page buffer 34 may operate according to the control signal CTRL provided from the control logic 38.

The data I/O circuit 36 may be electrically connected to the page buffer 34 through a plurality of data lines DLs. During the program operation, the data I/O circuit 36 may receive the data DATA from a memory controller (not shown) and provide program data DATA to the page buffer 34 based on a column address C_ADDR provided from the control logic 38. The data I/O circuit 36 may provide read data DATA stored in the page buffer 34 to the memory controller based on the column address C_ADDR provided from the control logic 38 during the read operation.

The data I/O circuit 36 may pass the input address or the command to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and the column address C_ADDR to the data I/O circuit 36. The control logic 38 may generate various internal control signals used within the semiconductor device 10 in response to the control signal CTRL. For example, the control logic 38 may adjust voltage levels provided to the word lines WL and the bit lines BL when performing the memory operation, such as a program operation or an erase operation.

The CSL driver 39 may be electrically connected to the memory cell array MCA through a common source line CSL. The CSL driver 39 may apply a common source voltage (e.g., a power supply voltage) or a ground voltage to the common source line CSL based on a control signal CTRL_BIAS of the control logic 38.

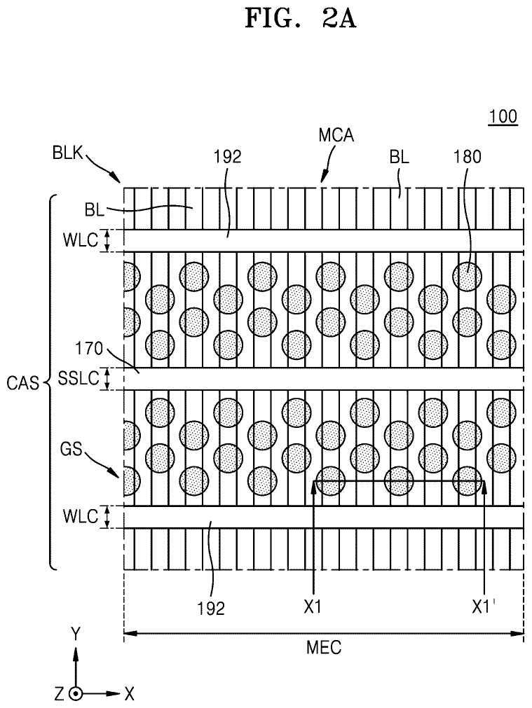

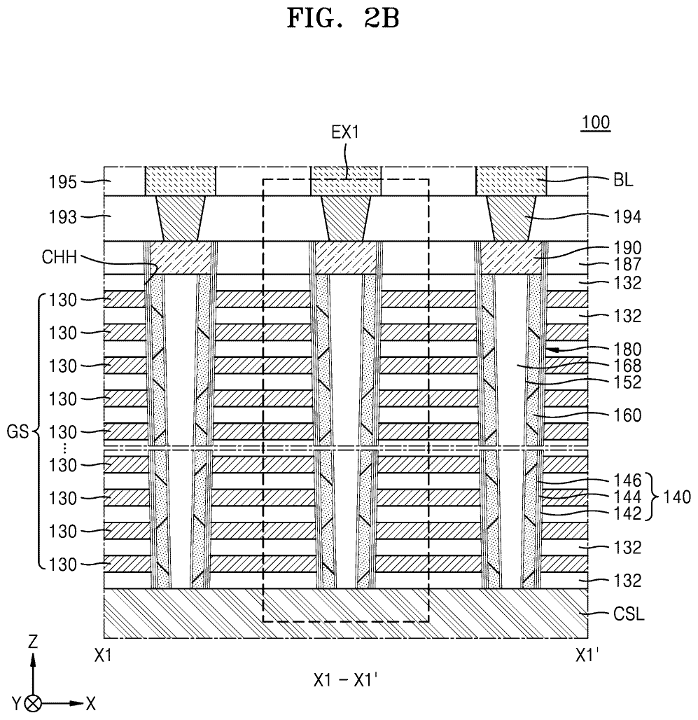

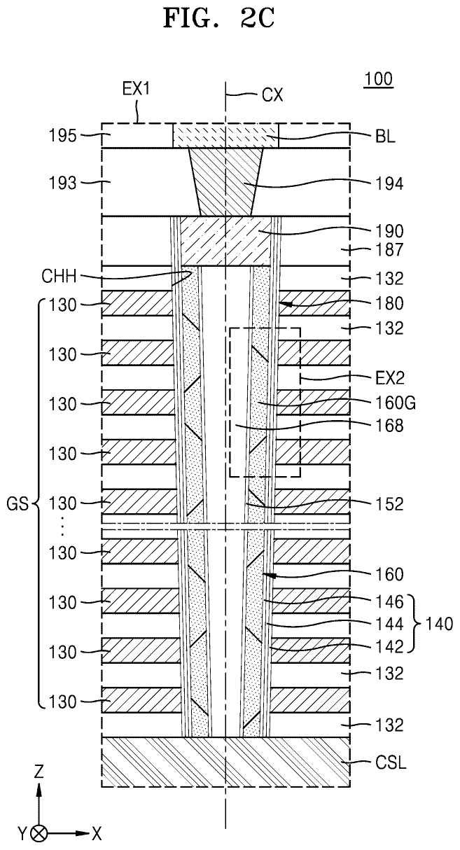

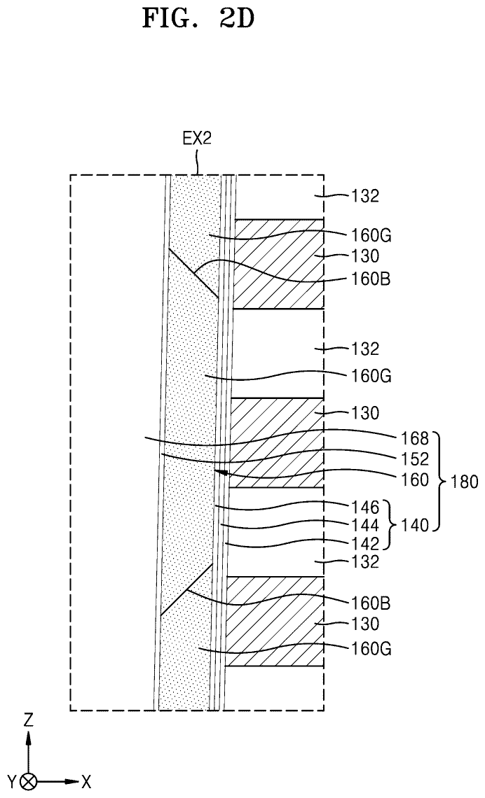

FIG. 2A is a plan layout showing some components of a cell array structure CAS of a semiconductor device 100 according to some embodiments. FIG. 2B is a cross-sectional view of some regions of a cross-section taken along line X1-X1′ in FIG. 2A. FIG. 2C is an enlarged cross-sectional view of a region indicated by “EX1” in FIG. 2B. FIG. 2D is an enlarged cross-sectional view of a region indicated by “EX2” in FIG. 2C. FIGS. 2A and 2B illustrate some configurations of a memory cell block BLK corresponding to one of the plurality of memory cell blocks BLK1 to BLKp in FIG. 1.

Referring to FIGS. 2A to 2D, the semiconductor device 100 includes a cell array structure CAS, wherein the cell array structure CAS may include a memory cell region MEC in which a memory cell array MCA is arranged.

The cell array structure CAS may include a common source line CSL and a memory cell array MCA disposed on the common source line CSL. The memory cell array MCA may include a gate stack GS consisting of a plurality of gate lines 130. The plurality of gate lines 130 included in the gate stack GS may extend, e.g., lengthwise, in a horizontal direction parallel to the common source line CSL and overlap with each other in a vertical direction (Z direction). The plurality of gate lines 130 may include the word lines WL, the ground select lines GSL, and the string select lines SSL illustrated in FIG. 1.

As illustrated in FIG. 2B, the cell array structure CAS may include a stacked structure including a gate stack GS and a plurality of insulating patterns 132. The gate stack GS may include the plurality of gate lines 130 overlapping with each other in the vertical direction (Z direction) on the common source line CSL and spaced apart from each other in the vertical direction (Z direction). The plurality of insulating patterns 132 may be positioned between the common source line CSL and the plurality of gate lines 130 and between the plurality of gate lines 130. The stacked structure may further include an intermediate insulating film 187 covering an uppermost insulating pattern 132 of the plurality of insulating patterns 132. Among the plurality of gate lines 130, a gate line 130 furthest from the common source line CSL, e.g., in the vertical direction, may be covered by the insulating pattern 132 and the intermediate insulating film 187. The plurality of insulating patterns 132 and the intermediate insulating film 187 may include silicon oxide (SiO), silicon nitride (SiN), or silicon oxynitride SiON.

A plurality of conductive pads 190 may be spaced apart from the common source line CSL in the vertical direction (Z direction) with the stacked structure including the plurality of gate lines 130 and the plurality of insulating patterns 132 positioned therebetween. The common source line CSL may be a conductive layer.

The plurality of gate lines 130 may each include a metal, a conductive metal nitride, a metal silicide, an impurity-doped semiconductor, or a combination thereof. For example, the plurality of gate lines 130 may each include, but are not limited to, tungsten (W), nickel (Ni), cobalt (Co), tantalum (Ta), tungsten nitride (WN), titanium nitride (TiN), tantalum nitride (TaN), doped polysilicon, tungsten silicide (WSi₂), nickel silicide (NiSi₂), cobalt silicide (CoSi₂), tantalum silicide (TaSi₂), or a combination thereof.

The plurality of conductive pads 190 and the common source line CSL may each include a semiconductor material, a metal, a conductive metal nitride, or a combination thereof. For example, the plurality of conductive pads 190 and the common source line CSL may each include, but are not limited to, doped polysilicon, tungsten (W), titanium (Ti), tantalum (Ta), copper (Cu), aluminum (Al), TiNi₂, TaNi₂, WNi₂, or a combination thereof.

The cell array structure CAS may include a plurality of vertical holes CHH passing through the stacked structure in the vertical direction (Z direction) and a plurality of channel structures 180 arranged in the plurality of vertical holes CHH, respectively. The plurality of channel structures 180 may each include multiple dielectric films 140, a channel film 160, a bond-inducing oxide film 152, and an insulating plug 168, which are sequentially stacked from a side wall of a corresponding vertical hole CHH in a direction receding from the plurality of gate lines 130 and approaching a center CX of the channel structure 180 and/or a center of the corresponding vertical hole CHH.

According to some embodiments, the channel film 160 may extend lengthwise in the vertical direction (Z direction) within the vertical hole CHH. One end of the channel film 160 in the vertical direction (Z direction) may be in contact with a corresponding conductive pad 190 and the other end of the channel film 160 in the vertical direction (Z direction) may be in contact with the common source line CSL.

According to some embodiments, the multiple dielectric films 140 may cover the side/inner wall of the vertical hole CHH and may be positioned between the channel film 160 and the plurality of gate lines 130. For example, the multiple dielectric films 140 may extend, e.g., lengthwise, in the vertical direction (Z direction) and may include portions positioned between the channel film 160 and the gate lines 130, and portions positioned between the channel film 160 and the insulating patterns 132. For example, the multiple dielectric films 140 may horizontally surround an outer wall of the channel film 160. For example, the multiple dielectric films 140 may contact the outer wall (sidewall) of the channel film 160.

In some embodiments, the multiple dielectric films 140 may include a first silicon insulating film 142, a silicon oxynitride film 144, and a second silicon oxide film 146, which are sequentially stacked on the inner/side wall of the vertical hole CHH in a direction approaching the center CX of the channel structure 180. The multiple dielectric films 140 may be multi-tunneling dielectric films or tunneling dielectric films.

In some embodiments, the conductive pad 190 may be positioned within the vertical hole CHH and the multiple dielectric films 140 may surround the sidewall of the conductive pad 190. For example, the multiple dielectric films 140 may include a portion placed/interposed between the conductive pad 190 and the intermediate insulating film 187.

According to some embodiments, the bond-inducing oxide film 152 may be disposed on the inner wall of the channel film 160. For example, the bond-inducing oxide film 152 may be in contact with the inner wall of the channel film 160 and extend lengthwise in the vertical direction (Z direction). According to some embodiments, the insulating plug 168 is arranged in a space defined by the bond-inducing oxide film 152 and may be surrounded by the bond-inducing oxide film 152. For example, the bond-inducing oxide film 152 may contact a sidewall of the insulating plug 168.

According to some embodiments, the channel film 160 may include polycrystalline silicon including a plurality of grains 160G. The channel film 160 may include a channel grain boundary 160B that is a boundary between the plurality of grains 160G. The channel film 160 is shown to include polycrystalline silicon in the drawings in that the channel film 160 includes a plurality of grains 160G. However, the channel film 160 may be understood as having a single crystalline-like structure, e.g., in electrical characteristic aspects, in that the size of each of the plurality of grains 160G is relatively large. For example, sizes of the grains 160G of the channel film 160 may be sufficiently large such that electrical characteristics of the channel film 160 is close to an electrical characteristics of a channel film having a single crystalline structure. According to some embodiments, the size of individual grains of the plurality of grains 160G may be from about 0.5 μm to about 14 μm.

The size of each of the plurality of grains 160G may be defined as follows. First, the area of the grain 160G is measured in a cross section (e.g., a cross-section as formed on a plane) passing through the channel film 160. For example, the area of the grain 160G is measured in a cross-section perpendicular to the common source line CSL and passing through the channel film 160. Next, a circle having the same area as the calculated area of the grain 160G is calculated/determined, and then the radius thereof is calculated/determined. The radius may be defined as the size of the grain 160G, such that the radius may be between about 0.5 μm and about 14 μm.

According to some embodiments, the number of grains 160G per length of the channel film 160 in the vertical direction (Z direction) may be from about 0.07 grain/μm to about 2 grains/μm. For example, when the length of the channel film 160 in the vertical direction (Z direction) is 18 μm, the number of grains 160G included along a line extending in the length direction of the channel film 160 may be about 4 to about 36.

In some embodiments, the plurality of grains 160G having sizes in the range described above may be uniformly distributed from the bottom to the top of the channel film 160. For example, configurations/arrangements of grains 160G in the channel film 160 may be substantially the same throughout the channel film 160. For example, average sizes of the grains 160G per unit volume (e.g., one cubic micrometers or one tenth of the total volume of the channel film 160, etc.) may be substantially the same (e.g., within 5% of variation) throughout the channel film 160, e.g., in each channel. For example, most of the grains 160G in the channel film 160, e.g., on volume basis, may have similar sizes within the range described above. For example, the sizes of the grains 160G may have a normal distribution (Gaussian distribution) in the channel film 160, e.g., on volume basis. The grains 160G in a first portion adjacent to the top of the channel film 160, e.g., adjacent to the conductive pad 190, and the grains 160G in a second portion adjacent to the bottom of the channel film 16, e.g., adjacent to the common source line CSL, may have similar sizes to each other, within a range of about 0.5 μm to about 14 μm.

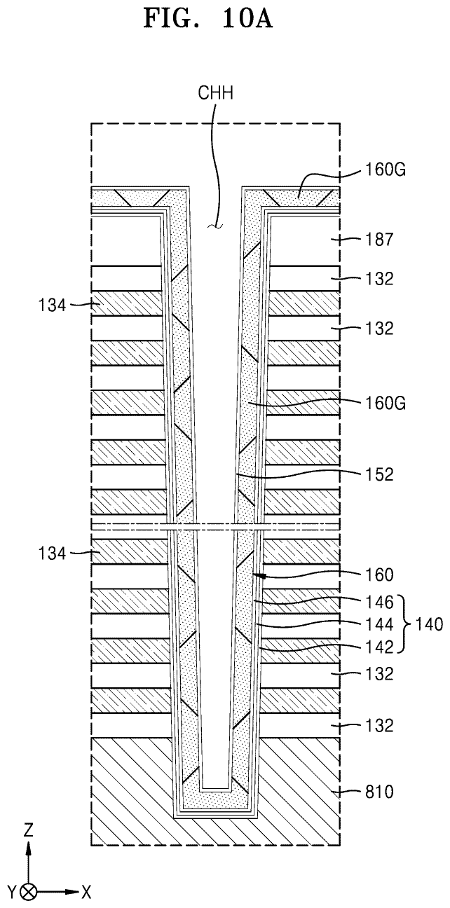

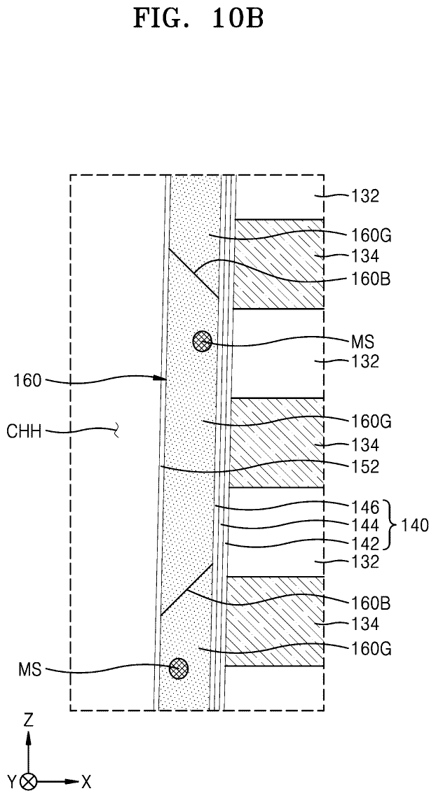

In some embodiments, the plurality of grains 160G may each include a different crystal face from crystal faces of other grains 160G. As the channel film 160 including a polycrystalline silicon film is formed from an amorphous silicon film by using metal seeds MS (see FIGS. 10A and 10B), the polycrystalline silicon film of the channel film 160 may include the plurality of grains 160G. Therefore, since the plurality of grains 160G are initiated and formed around the metal seeds MS, respectively, the plurality of grains 160G may each include any crystal face (e.g., an arbitrary crystal face). In this case, the crystal plane may be a plane that represents the outer shape/surface of a crystal/grain and may be parallel to a lattice plane of the crystal/grain. The plurality of grains 160G may each have a different size from other grains 160G.

For example, the plurality of grains 160G may include a first grain and a second grain adjacent to the first grain. The first grain may include a first crystal face and the second grain may include a second crystal face different from the first crystal face. For example, the second grain may not include a crystal face the same as the first crystal face, e.g., a crystal face parallel to the first crystal face, and the first grain may not include a crystal face the same as the second crystal face, e.g., a crystal face parallel to the second crystal face.

According to some embodiments, the channel film 160 may include the plurality of grains 160G having a relatively large size, thereby improving electrical stability and reliability of the semiconductor device 100. A channel film of a semiconductor device according to a first comparative example is formed by a solid-phase crystallization method and has a polycrystalline silicon structure in which the size of grains is less than 0.5 μm and the number of grains per length is greater than 2 grains/μm. In this case, the number of grain boundaries between the grains is excessively increased compared with the above described example embodiments, thereby deteriorating the reliability of the semiconductor device according to the first comparative example. A channel film of a semiconductor device according to a second comparative example includes a monocrystalline silicon structure formed by a metal-induced lateral crystallization method from one end of a preliminary channel film including amorphous silicon. When the length of the channel film in the vertical direction (Z direction) according to the second comparative example is relatively long, for example, 15 μm or more, a high level of technical difficulty is required to implement the channel film as one single crystal silicon. During the crystallization process, while a single crystal grows from one end of the channel film, the amorphous silicon of the preliminary channel film may be crystallized at the other end opposite to the one end thereof by a solid-phase crystallization, which increases the deviation in the size of the grains in the vertical direction, thereby deteriorating the reliability of the semiconductor device.

In some embodiments, the channel film 160 may include a metal. For example, the metal may include or may be Ni, palladium (Pd), Ti, silver (Ag), gold (Au), Al, tin (Sn), antimony (Sb), Cu, Co, chromium (Cr), molybdenum (Mo), terbium (Tb), ruthenium (Ru), cadmium (Cd), platinum (Pt), or a combination thereof.

In some embodiments, the concentration of the metal in the channel film 160 may be less than or equal to about 10¹³ at/cm². The metal may be part of metal seeds MS (see FIGS. 10A and 10B) formed by a method of manufacturing a semiconductor device to be described later. When the concentration of the metal in the channel film 160 exceeds the above-described range, the electrical characteristics of the channel film 160 may deteriorate, thereby deteriorating the memory performance of the semiconductor device 100.

In some embodiments, the bond-inducing oxide film 152 may include or may be a silicon oxide film. The bond-inducing oxide film 152 may be an oxide film other than the silicon oxide film in certain embodiments. In some embodiments, the insulating plug 168 may include or may be a silicon oxide film but is not limited thereto.

In the cell array structure CAS, the plurality of bit lines BL may be positioned on the plurality of channel structures 180. A plurality of bit line contact pads 194 may be positioned between the plurality of channel structures 180 and the plurality of bit lines BL. The conductive pad 190 positioned on one end of each of the plurality of channel structures 180 may be electrically connected to a corresponding one of the plurality of bit lines BL through the bit line contact pad 194. The plurality of bit line contact pads 194 may be insulated from each other by a first upper insulating film 193 and the plurality of bit lines BL may be insulated from each other by a second upper insulating film 195. For example, the plurality of bit line contact pads 194 may be formed in and surrounded by a first upper insulating film 193 and the plurality of bit lines BL may be formed in and surrounded by a second upper insulating film 195.

In some embodiments, the plurality of bit line contact pads 194 and the plurality of bit lines BL may each include a metal, a conductive metal nitride, or a combination thereof. For example, the plurality of bit line contact pads 194 and the plurality of bit lines BL may each include W, Ti, Ta, Cu, Al, TiN, TaN, WN, or a combination thereof. The first upper insulating film 193 and the second upper insulating film 195 may each include or may be a silicon oxide film, a silicon nitride film, or a combination thereof.

As illustrated in FIG. 2A, a plurality of word line cut regions WLC in the cell array structure CAS may extend in a first horizontal direction (X direction). The plurality of word line cut regions WLC may define a width of the gate stack GS in a second horizontal direction (Y direction). The plurality of word line cut regions WLC may be filled with a word line cut structure 192. In some embodiments, the word line cut structure 192 may include or may be an insulating film, polysilicon, a metal film, or a combination thereof. In some embodiments, the word line cut structure 192 may include or may be, but is not limited to, a silicon oxide film, a silicon nitride film, a polysilicon film, a tungsten film, or a combination thereof.

In the memory cell array MCA, two neighboring string select lines SSL (see FIG. 1) in the second horizontal direction (Y direction) may be spaced apart from each other with a string select line cut region SSLC therebetween. The string select line cut region SSLC may be filled with the insulating film 170. In some embodiments, the insulating film 170 may include or may be an oxide film, a nitride film, or a combination thereof. In some embodiments, at least a portion of the string select line cut region SSLC may be formed of an air gap. For example, the air gap may be filled with air. As used herein, the term “air” may refer to atmospheric air or other gases that may be present during the manufacturing process. The air gap may comprises a gap forming a vacuum therein in certain embodiments.

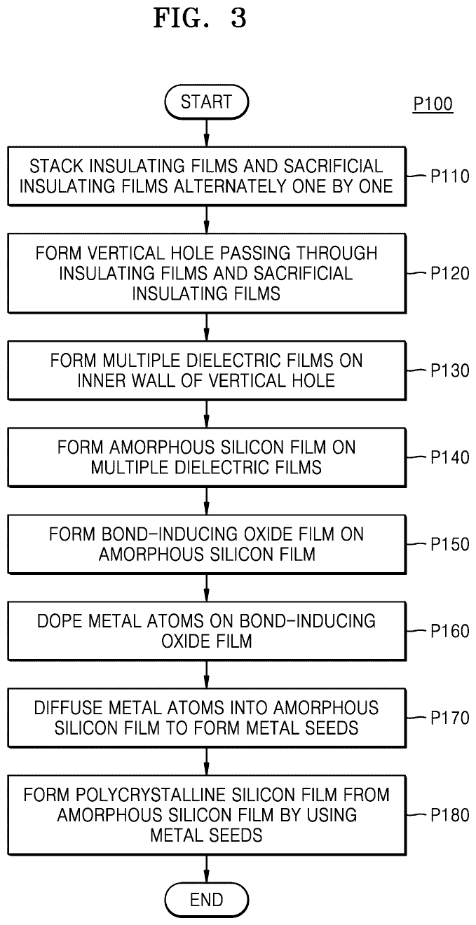

FIG. 3 is a flowchart of a method of manufacturing a semiconductor device, according to some embodiments.

Referring to FIG. 3, a method P100 of manufacturing a semiconductor device according to some embodiments may include stacking a plurality of insulating films and a plurality of sacrificial insulating films alternately one by one (P110), forming a vertical hole passing through the plurality of insulating films and the plurality of sacrificial insulating films (P120), forming multiple dielectric films on an inner wall of the vertical hole (P130), forming an amorphous silicon film on the multiple dielectric films (P140), forming a bond-inducing oxide film on the amorphous silicon film (P150), doping/bonding metal atoms on the bond-inducing oxide film (P160), diffusing the metal atoms into the amorphous silicon film to form metal seeds (P170), and forming a polycrystalline silicon film from the amorphous silicon film by using the metal seeds (P180).

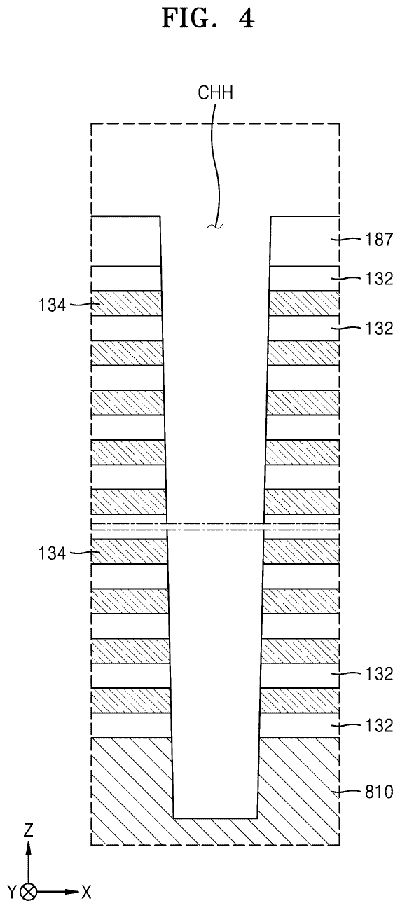

The technical features of each operation of the above-described method P100 for manufacturing the semiconductor device may be described in detail below with reference to FIG. 3 together with FIGS. 4 to 15.

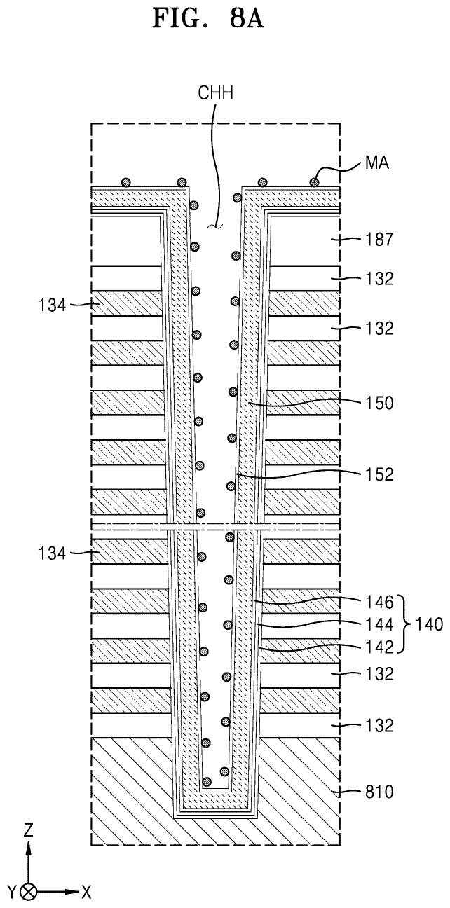

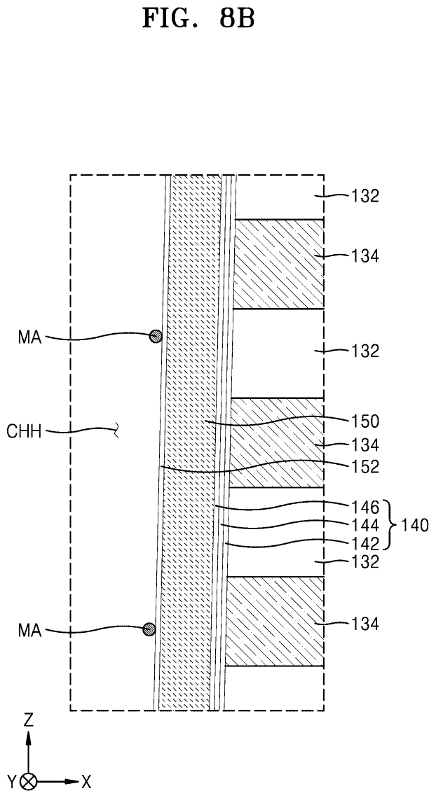

FIGS. 4 to 15 are cross-sectional views shown in process order to explain a method of manufacturing a semiconductor device according to some embodiments, wherein FIGS. 4, 5, 6, 7, 8A, 10A, 11, 12, 13, 14, and 15 are enlarged views of a region corresponding to the region indicated by “EX1” in FIG. 2B and FIGS. 8B, 9, and 10B are enlarged views of a region corresponding to the region indicated by “EX2” in FIG. 2C. In FIGS. 4 to 15, the same reference numerals as those in FIGS. 2A to 2D indicate the same elements/members and duplicate descriptions thereof are omitted.

Referring to FIG. 4, after the plurality of insulating films and the plurality of sacrificial insulating films are alternately stacked one by one (P110) on a sacrificial substrate 810, an intermediate insulating film 187 may be formed over the uppermost insulating film among the plurality of insulating films. Thereafter, vertical hole CHH extending lengthwise in the vertical direction (Z direction) through the plurality of insulating films, the plurality of sacrificial insulating films, and the intermediate insulating film 187 are formed (P120), thereby forming a plurality of insulating patterns 132 and a plurality of sacrificial patterns 134 defining the vertical hole CHH. The vertical hole CHH may pass through a portion of the sacrificial substrate 810.

In some embodiments, the sacrificial substrate 810 may include silicon. The plurality of insulating patterns 132 may include a silicon oxide film and the plurality of sacrificial patterns 134 may include a silicon nitride film. Each of the plurality of sacrificial patterns 134 may secure a space for forming the gate stack GS (see FIGS. 2B to 2D) in a subsequent process.

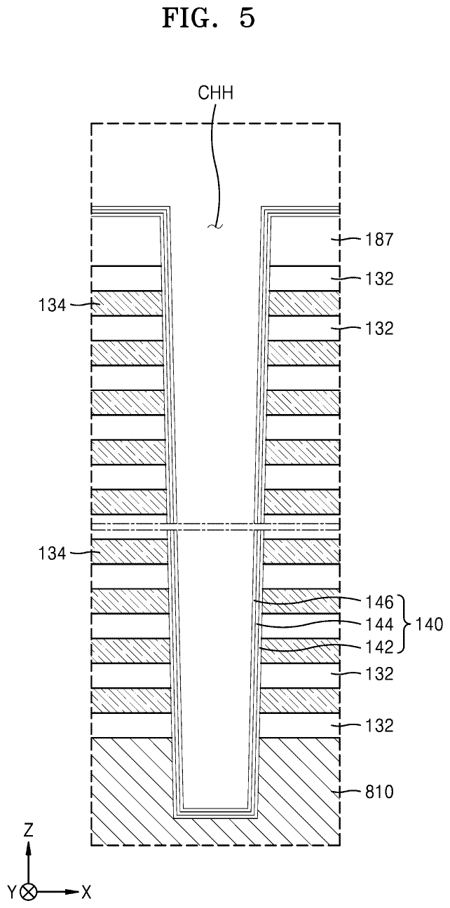

Referring to FIG. 5, in the result of FIG. 4, a first silicon oxide film 142, a silicon oxynitride film 144, and a second silicon oxide film 146 are sequentially formed on surfaces exposed inside and outside the vertical hole CHH to form multiple dielectric films 140 (P130). For example, the first silicon insulating film 142, the silicon oxynitride film 144, and the second silicon oxide film 146 may be sequentially stacked on the inner wall of the vertical hole CHH in a direction approaching the center CX thereof (see FIG. 2C). The first silicon insulating film 142, the silicon oxynitride film 144, and the second silicon oxide film 146 have the same thickness in FIG. 5 but are not limited thereto.

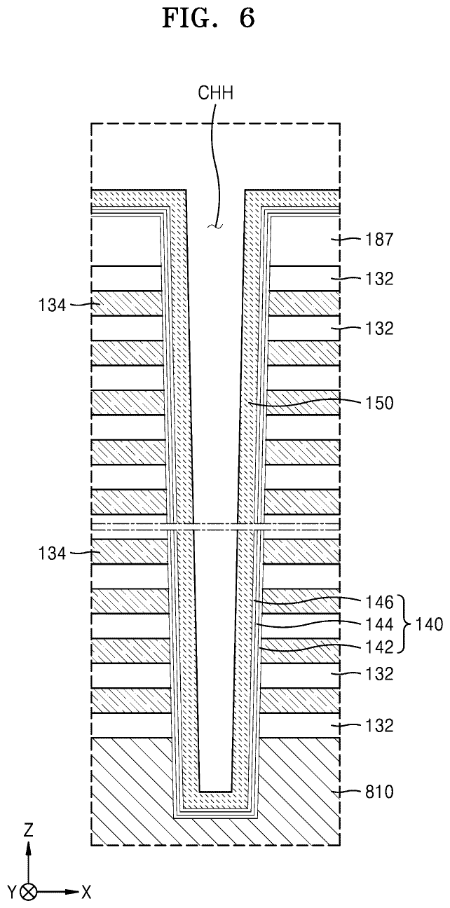

Referring to FIG. 6, in the result of FIG. 5, an amorphous silicon film 150 may be formed on the multiple dielectric films 140 (P140). In some embodiments, the amorphous silicon film 150 may cover an exposed surface of the multiple dielectric films 140 and may partially fill the vertical hole CHH. For example, the amorphous silicon film 150 may be in contact with an exposed surface of the second silicon oxide film 146 and formed along a surface profile of the second silicon oxide film 146. In some embodiments, the amorphous silicon film 150 may be formed through an atomic layer deposition (ALD) process or a chemical vapor deposition (CVD) process. The amorphous silicon film 150 may have a thickness greater than each of thicknesses of the first silicon insulating film 142, the silicon oxynitride film 144, and the second silicon oxide film 146. In some embodiments, the amorphous silicon film 150 may have a thickness greater than the sum of the thicknesses of the multiple dielectric films 140.

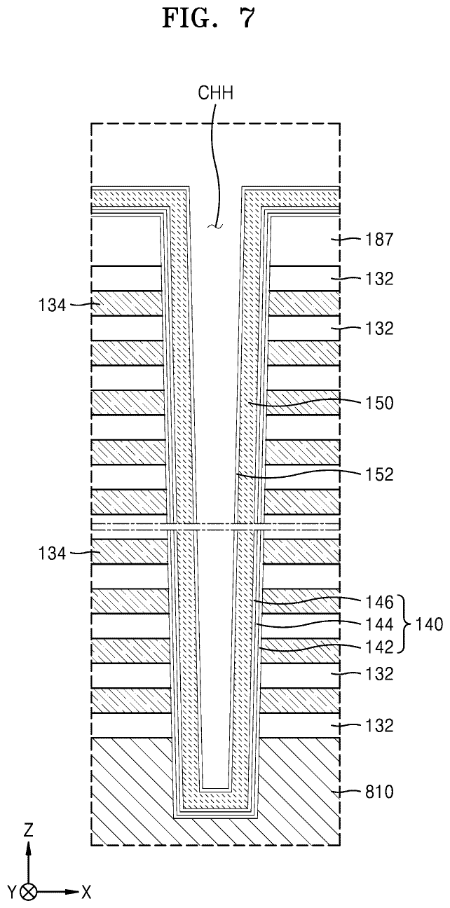

Referring to FIG. 7, in the result of FIG. 6, a bond-inducing oxide film 152 may be formed on the amorphous silicon film 150 (P150). In some embodiments, the bond-inducing oxide film 152 may cover an exposed surface of the amorphous silicon film 150 and may partially fill the vertical hole CHH. For example, the bond-inducing oxide film 152 may be in contact with the exposed surface of the amorphous silicon film 150 and may be formed along the exposed surface profile of the amorphous silicon film 150.

In some embodiments, the bond-inducing oxide film 152 may be formed on the amorphous silicon film 150 through the ALD or CVD process. In other embodiments, the bond-inducing oxide film 152 may be formed by oxidizing a portion of the exposed surface of the amorphous silicon film 150. For example, the oxidation process may include or may be a natural oxidation process or a dry oxidation process. In some embodiments, the bond-inducing oxide film 152 may include or may be a silicon oxide film.

Referring to FIGS. 8A and 8B, in the result of FIG. 7, an exposed surface of the bond-inducing oxide film 152 may be doped with metal atoms MA (P160). The doping/bonding of the metal atoms MA may include forming a covalent bond between the metal atoms MA and hydroxy groups (—OH) on the surface of the bond-inducing oxide film 152.

In some embodiments, the doping/bonding of the metal atoms MA may be performed by a gas-phase deposition process using a metal precursor gas. For example, the gas-phase deposition process may be performed at a temperature of about 100° C. to about 350° C. and a pressure of about 0 Torr to about 10 Torr.

In some embodiments, the metal atoms MA may include or may be Ni, Pd, Ti, Ag, Au, Al, Sn, Sb, Cu, Co, Cr, Mo, Tb, Ru, Cd, and Pt, but is not limited thereto.

In some embodiments, the metal atoms MA may include or may be nickel and the nickel precursor may include or may be halogen ligands including nickel(II) chloride and nickel(II) bromide, alkyl ligands including bis(cyclopentadienyl)nickel(II) and nickelocene, alkoxy ligands including nickel(II) ethoxide and nickel(II) isopropoxide, and amino ligands including bis(dimethylglyoximato)nickel(II) and tetrakis(dimethylamido)nickel(0).

In some embodiments, the metal atoms MA may be doped/bonded to the surface of the bond-inducing oxide film 152 to be uniformly distributed over the top to bottom of the vertical hole CHH. For example, the metal atoms MA may be doped to be uniformly distributed on the surface of the bond-inducing oxide film 152 within the vertical hole CHH. In a case in which the bond-inducing oxide film 152 forming process and/or the gas-phase deposition process are omitted, the metal atoms MA may be concentrated and deposited only on the top of the vertical hole CHH, thereby reducing the reliability of the semiconductor device. For example, the bond-inducing oxide film 152 and the gas-phase deposition process may be helpful for uniform doping of the metal atoms MA into the amorphous silicon film 150 so that the reliability of the semiconductor device may be improved. According to the method P100 of manufacturing the semiconductor device according to some embodiments, the bonding of the metal atoms MA may be more easily performed/accomplished through the bond-inducing oxide film 152 to be adjusted to a very small concentration and may be uniformly distributed over the top to the bottom of the vertical hole CHH.

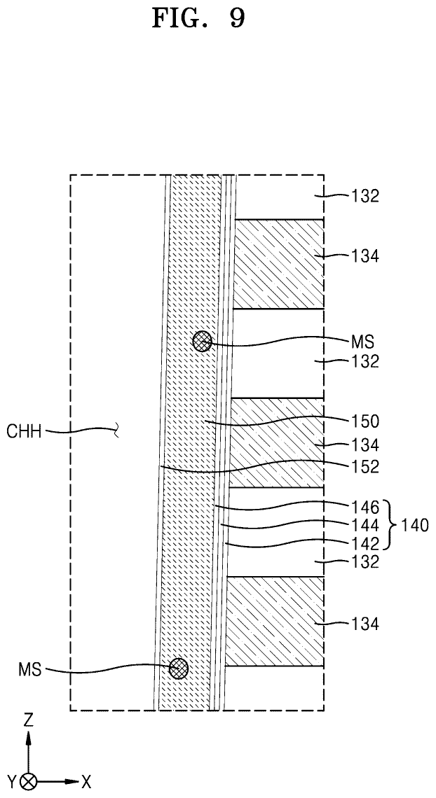

Referring to FIG. 9, in the result of FIGS. 8A and 8B, the metal atoms MA may be diffused into the amorphous silicon film 150 through a first heat treatment process to form metal seeds MS (P170). As the diffusion process is performed when the metal atoms MA are uniformly distributed on the bond-inducing oxide film 152 from the top to the bottom of the vertical hole CHH, the metal seeds MS may be distributed, e.g., uniformly, within the amorphous silicon film 150 from the top to the bottom of the vertical hole CHH. In some embodiments, the metal may include or may be Ni and the metal seed MS may include or may be NiSi₂. In some embodiments, the first heat treatment process may be performed at a temperature from about 400° C. to about 500° C.

Referring to FIGS. 10A and 10B, in the result of FIG. 9, a channel film 160 including a polycrystalline silicon film may be formed from the amorphous silicon film by using the metal seeds MS through a second heat treatment process (P180). The polycrystalline silicon film of the channel film 160 may include a plurality of grains 160G. In some embodiments, since the plurality of grains 160G are formed around the uniformly distributed metal seeds MS, the plurality of grains 160G of generally uniform size may be distributed from the top to the bottom of the vertical hole CHH. For example, the size of each of the plurality of grains 160G may be from about 0.5 μm to about 14 μm. In some embodiments, the number of grains 160G per length of the channel film 160 in the vertical direction (Z direction) may be about 0.07 grains/μm to about 2 grains/μm.

In some embodiments, the second heat treatment may be performed below a solid-phase crystallization temperature of silicon. In some embodiments, the temperature of the second heat treatment may be about 500° C. to about 600° C. In the method of manufacturing the semiconductor device according to some embodiments, the second heat treatment may be performed at a relatively low temperature below the solid-phase crystallization temperature of silicon, for example, less than about 600° C. Accordingly, except the grain growth around the metal seeds MS, the grain growth may be prevented by the solid-phase crystallization method and the channel film 160 may be formed to have a polycrystalline silicon structure with a relatively large grain size. In addition, in some embodiments, although random nucleation and growth occurs at or below the temperature of the second heat treatment and grains are formed in some areas of the amorphous silicon film 150 by the solid-phase crystallization method, the grain growth occurs simultaneously around the metal seeds MS uniformly distributed across the vertical hole CHH, e.g., from the top to the bottom, thereby preventing areas of the channel film 160 from remaining as amorphous silicon or areas of the channel film 160 having grain sizes less than 0.5 μm from being excessively enlarged. For example, the second heat treatment may be helpful to reduce areas of the channel film 160 having amorphous silicon and/or small grain sizes less than 0.5 μm.

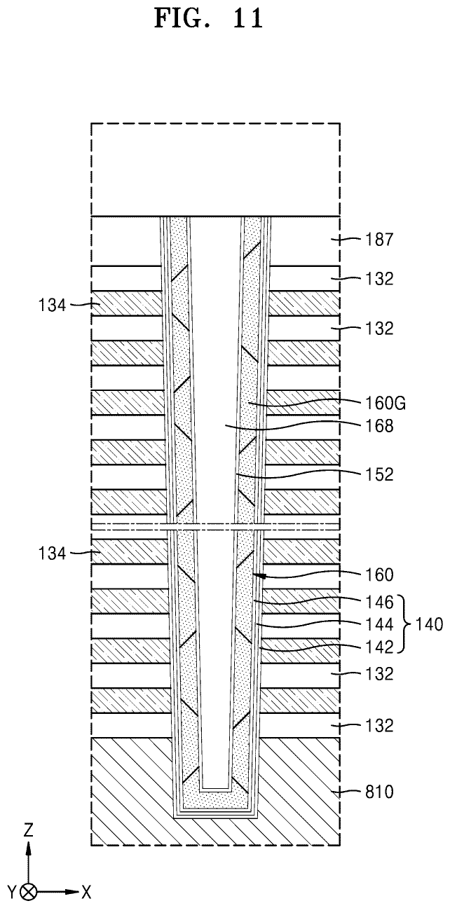

Referring to FIG. 11, in the result of FIGS. 10A and 10B, after an insulating film filling the remaining portion of the vertical hole CHH is formed, an insulating plug 168 may be formed by planarizing such that a top surface of the intermediate insulating film 187 is exposed.

In other embodiments, a gettering process for removing the metal from the channel film 160 may be further performed before the insulating film for the insulating plug 168 is formed in the vertical hole CHH. For example, by using the bond-inducing oxide film 152 as a metal adsorption film or additionally forming a separate metal adsorption film on the bond-inducing oxide film 152, the metal in the channel film 160 may be adsorbed to the metal adsorption film through heat treatment. Thereafter, the metal may be removed by removing the bond-inducing oxide film 152 including the adsorbed metal or the metal adsorption film including adsorbed metal. Accordingly, the electrical reliability of the semiconductor device 100 may be improved.

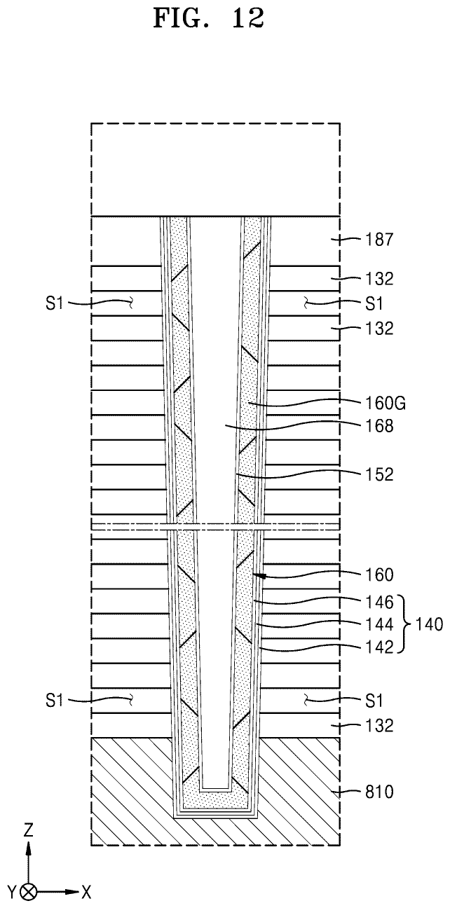

Referring to FIG. 12, in the result of FIG. 11, the plurality of sacrificial patterns 134 may be removed to form a plurality of gate spaces S1. To form the plurality of gate spaces S1, the plurality of word line cut regions WLC described with reference to FIG. 2A may be formed in advance and the plurality of sacrificial patterns 134 may be removed through the plurality of word line cut regions WLC. After the plurality of sacrificial patterns 134 are removed, the first silicon insulating film 142 may be exposed through the plurality of gate spaces S1.

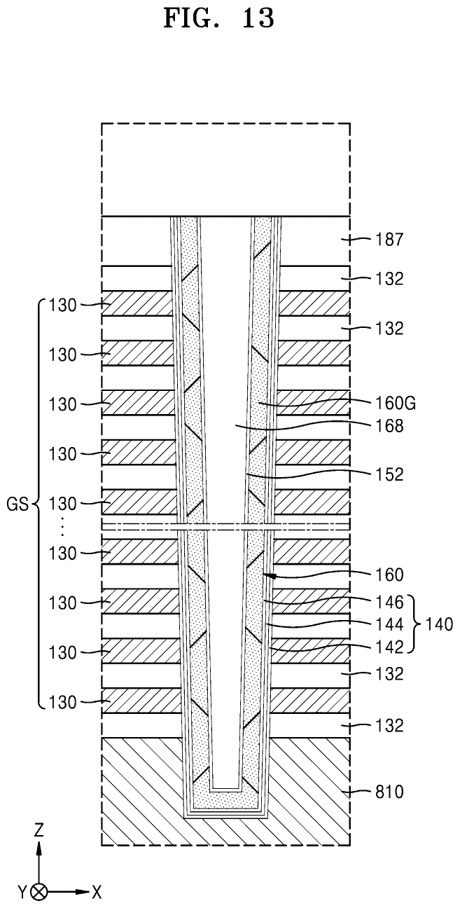

Referring to FIG. 13, in the result of FIG. 12, the plurality of gate spaces S1 may be filled with the plurality of gate lines 130. Thereafter, as illustrated in FIG. 2A, the inside of each of the plurality of word line cut regions WLC may be filled with the word line cut structure 192.

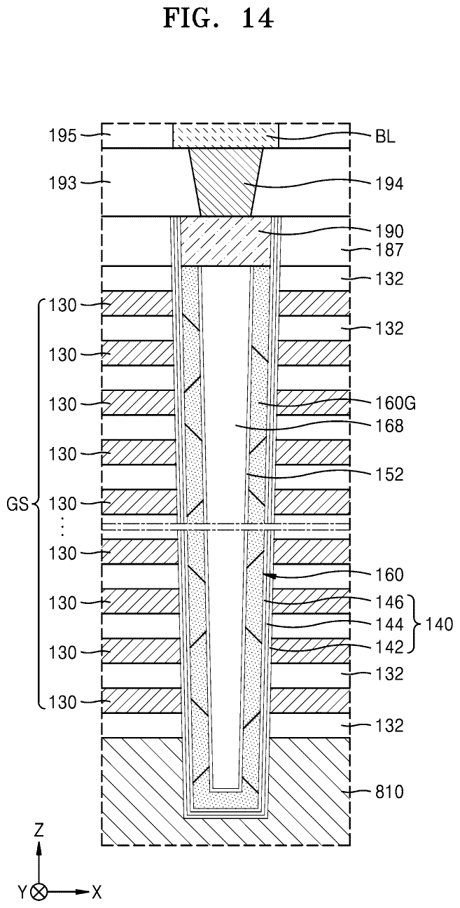

Referring to FIG. 14, in the result of FIG. 13, a portion of each of the channel film 160 and the insulating plug 168 may be removed to provide a space at a top of the vertical hole CHH and form the conductive pad 190 filling the space.

Thereafter, a first upper insulating film 193 covering the intermediate insulating film 187 and the conductive pad 190 and a bit line contact pad 194 passing through the first upper insulating film 193 and electrically connected to the conductive pad 190 may be formed, a second upper insulating film 195 covering the first upper insulating film 193 and the bit line contact pad 194 may be formed, and a bit line BL passing through the second upper insulating film 195 and electrically connected to the bit line contact pad 194 may be formed.

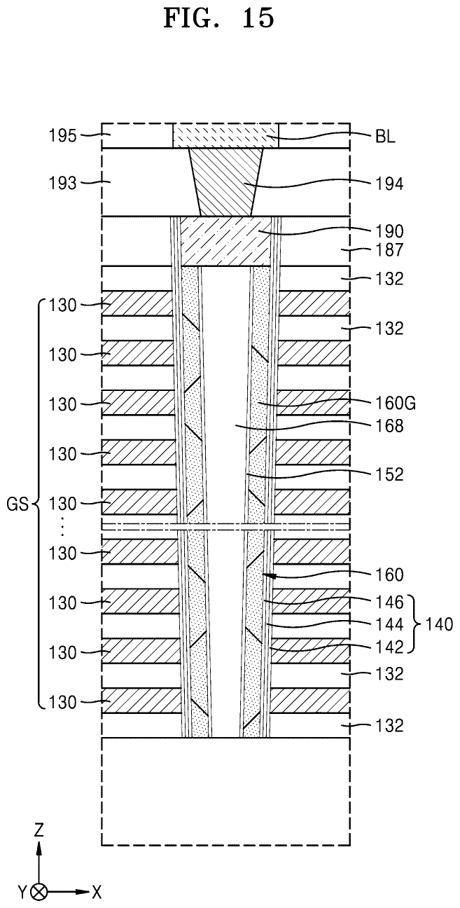

Referring to FIG. 15, in the result of FIG. 14, the sacrificial substrate 810 may be removed and the resulting product may be planarized to expose the insulating pattern 132, the multiple dielectric films 140, the channel film 160, and the insulating plug 168. Thereafter, the common source line CSL (see FIG. 2C) may be formed to cover the exposed surfaces of the insulating pattern 132, the multiple dielectric films 140, the channel film 160, and the insulating plug 168.

Although the methods of manufacturing the semiconductor device 100A illustrated in FIG. 2A to FIG. 2D have been described above with reference to FIGS. 3 to 15, it will be understood by those skilled in the art that various modifications and changes can be made within the scope of the inventive concept to manufacture semiconductor devices having various structures with various modifications and changes within the scope of the inventive concept.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A semiconductor device comprising:
a stacked structure in which a plurality of gate lines and a plurality of insulating patterns are alternately stacked in a vertical direction;
a channel film extending lengthwise in the vertical direction within a vertical hole passing through the stacked structure in the vertical direction, the channel film having a polycrystalline structure; and
multiple dielectric films between the plurality of gate lines and the channel film,
wherein the number of grains per length of the channel film along a line extending in the vertical direction is 0.07 grain/μm to 2 grains/μm.

2. The semiconductor device of claim 1, further comprising a bond-inducing oxide film positioned within a columnar space defined by the channel film and extending in the vertical direction in contact with a surface of the channel film.

3. The semiconductor device of claim 1, wherein a size of the grains of the channel film is 0.5 μm to 14 μm.

4. The semiconductor device of claim 1, wherein the channel film comprises a metal, and
wherein the metal has a concentration of 10¹³ at/cm² or less.

5. The semiconductor device of claim 4, wherein the metal comprises nickel.

6. The semiconductor device of claim 1, wherein the channel film comprises a plurality of grains, and
wherein the plurality of grains are uniformly distributed from the bottom to the top of the vertical hole.

7. The semiconductor device of claim 1, wherein the channel film comprises a plurality of grains, and
wherein the plurality of grains each have a different size from other grains.

8. The semiconductor device of claim 1, wherein the channel film comprises a plurality of grains, and
wherein the plurality of grains each have a different crystal face from other grains.

9. A semiconductor device comprising:
a peripheral circuit; and
a memory cell array,
wherein the memory cell array comprises:
a stacked structure in which a plurality of gate lines and a plurality of insulating patterns are alternately stacked in a vertical direction;
a channel film extending lengthwise in the vertical direction within a vertical hole passing through the stacked structure in the vertical direction and having a polycrystalline structure;
an oxide film positioned within a columnar space defined by the channel film and extending in the vertical direction in contact with a surface of the channel film; and
multiple dielectric films between the plurality of gate lines and the channel film,
wherein the channel film comprises a plurality of grains, and
wherein the number of grains per length of the channel film along a line extending in the vertical direction is 0.07 grain/μm to 2 grains/μm.

10. The semiconductor device of claim 9, wherein the plurality of grains are uniformly distributed from the bottom to the top of the vertical hole.

11. The semiconductor device of claim 9, wherein the plurality of grains each have a size of 0.5 μm to 14 μm.

12. The semiconductor device of claim 9, wherein the plurality of grains each have a different size from other grains.

13. The semiconductor device of claim 9, wherein the plurality of grains comprise a first grain and a second grain adjacent to the first grain, and
wherein the first grain comprises a first crystal face and the second grain comprises a second crystal face different from the first crystal face.

14. The semiconductor device of claim 9, wherein the channel film comprises a metal, wherein the metal has a concentration of 10¹³ at/cm² or less.

15. A method of manufacturing a semiconductor device, the method comprising:
alternately stacking a plurality of insulating films and a plurality of sacrificial insulating films one by one;
forming a vertical hole extending in a vertical direction through the plurality of insulating films and the plurality of sacrificial insulating films;
forming multiple dielectric films on an inner wall of the vertical hole;
forming an amorphous silicon film on the multiple dielectric films;
forming an oxide film on the amorphous silicon film;
bonding metal atoms on a surface of the oxide film by reacting a metal precursor gas with the surface of the oxide film;
forming metal seeds within the amorphous silicon film by diffusing the metal atoms; and
forming a channel film including polycrystalline silicon from the amorphous silicon film using the metal seeds.

16. The method of claim 15, wherein the bonding of the metal atoms comprises forming a covalent bond between the metal atoms and hydroxy groups on the surface of the oxide film through a gas-phase deposition process.

17. The method of claim 15, wherein the metal atoms are bonded on the surface of the oxide film to be uniformly distributed on the surface of the oxide film within the vertical hole.

18. The method of claim 15, wherein the channel film comprises a plurality of grains,
wherein the plurality of grains each have a size of 0.5 μm to 14 μm, and
wherein the grains of the channel film are uniformly distributed from the bottom to the top of the vertical hole.

19. The method of claim 15, wherein the number of grains per length of the channel film along a line extending in the vertical direction is 0.07 grain/μm to 2 grains/μm.

20. The method of claim 15, wherein the forming of the metal seeds comprises diffusing the metal atoms through a first heat treatment,
wherein the forming of the channel film comprises forming the polycrystalline silicon from the amorphous silicon film through a second heat treatment, and
wherein the second heat treatment is performed below a solid-phase crystallization temperature of silicon.
